(19) United States
(12) Patent Application Publication
(10) Pub. No.: US 2008/0256424 A1
(43) Pub. Date: Oct. 16, 2008

(54) INFORMATION BIT PUNCTURING FOR TURBO CODING WITH PARAMETER SELECTABLE RATE MATCHING TAILORED TO LOWER EB/NO WITHOUT DEGRADING BLER (BLOCK ERROR RATE) PERFORMANCE

(75) Inventors: Ba-Zhong Shen, Irvine, CA (US); Tak K. Lee, Irvine, CA (US)

Correspondence Address: GARLICK HARRISON & MARKISON, P.O. BOX 160727, AUSTIN, TX, 78716-0727, US

(73) Assignee: BROADCOM CORPORATION, Irvine, CA (US)

(21) Appl. No.: 12/101,505

(22) Filed: Apr. 11, 2008

Related U.S. Application Data
(60) Provisional application No. 60/923,246, filed on Apr. 13, 2007.

(51) Int. Cl. H03M 13/03; G06F 11/10

(52) U.S. Cl. 714/790; 714/E11.032

(57) ABSTRACT

Information bit puncturing for turbo coding with parameter selectable rate matching tailored to lower Eb/No without degrading BLER (Block Error Rate) performance. A means is presented herein by which puncturing is performed to each of three bit sequences from a turbo encoder (i.e., the systematic bits or information bits within an block to be turbo encoded, the parity bits output from a first constituent encoder, and the parity bits output from a second constituent encoder). The number of bit punctured from each of the parity bits output from the first constituent encoder and the parity bits output from the second constituent encoder need not be the same number of bits. The manner in which puncturing may be performed can be adaptive and/or changeable, in that, first puncturing parameters may be employed at a first time and second puncturing parameters may be employed at a second time, etc.

### CROSS REFERENCE TO RELATED PATENTS/PATENT APPLICATIONS

### Provisional Priority Claims

The present U.S. Utility Patent Application claims priority pursuant to 35 U.S.C. §119(e) to the following U.S. Provisional Patent Application which is hereby incorporated herein by reference in its entirety and made part of the present U.S. Utility Patent Application for all purposes:

1. U.S. Provisional Application Ser. No. 60/923,246, entitled “Information bit puncturing for turbo coding with parameter selectable rate matching tailored to lower Eb/No without degrading BLER (Block Error Rate),” (Attorney Docket No. BP6276), filed Apr. 13, 2007, pending.

### BACKGROUND OF THE INVENTION

1. Technical Field of the Invention

The invention relates generally to communication systems; and, more particularly, it relates to communication systems employing turbo coding.

2. Description of Related Art

Data communication systems have been under continual development for many years. One such type of communication system that has been of significant interest lately is a communication system that employs iterative error correction codes. Of those, one particular type of communication system that has received interest in recent years has been one which employs turbo codes (one type of iterative error correcting code). Communications systems with iterative codes are often able to achieve lower bit error rates (BER) than alternative codes for a given signal to noise ratio (SNR).

A continual and primary directive in this area of development has been to try continually to lower the SNR required to achieve a given BER within a communication system. The ideal goal has been to try to reach Shannon's limit in a communication channel. Shannon's limit may be viewed as being the data rate to be used in a communication channel, having a particular SNR, that achieves error free transmission through the communication channel. In other words, the Shannon limit is the theoretical bound for channel capacity for a given modulation and code rate.

The use of turbo codes providing such relatively lower error rates, while operating at relatively low data throughput rates, has largely been in the context of communication systems having a large degree of noise within the communication channel and where substantially error free communication is held at the highest premium. Some of the earliest application arenas for turbo coding were space related where accurate (i.e., ideally error free) communication is often deemed an essential design criterion. The direction of development then moved towards developing terrestrial-applicable and consumer-related applications. Still, based on the heritage of space related application, the focus of effort in the turbo coding environment then continued to be achieving relatively lower error floors, and not specifically towards reaching higher throughput.

More recently, focus in the art has been towards developing turbo coding, and variants thereof, that are operable to support higher amounts of throughput while still preserving the relatively low error floors offered within the turbo code context.

Generally speaking, within the context of communication systems that employ turbo codes, there is a first communication device at one end of a communication channel with encoder capability and second communication device at the other end of the communication channel with decoder capability. In many instances, one or both of these two communication devices includes encoder and decoder capability (e.g., within a bi-directional communication system).

### BRIEF SUMMARY OF THE INVENTION

The present invention is directed to apparatus and methods of operation that are further described in the following Brief Description of the Several Views of the Drawings, the Detailed Description of the Invention, and the claims. Other features and advantages of the present invention will become apparent from the following detailed description of the invention made with reference to the accompanying drawings.

### BRIEF DESCRIPTION OF THE SEVERAL VIEWS OF THE DRAWINGS

FIG. 1 illustrates an embodiment of a communication system.

FIG. 2 illustrates an embodiment of a turbo encoding module.

FIG. 3 illustrates an embodiment of an uplink encoding module that performs rate matching to only the parity bits output from a first constituent encoder and a second constituent encoder.

FIG. 4 illustrates an embodiment of a downlink encoding module that performs rate matching to only the parity bits output from a first constituent encoder and a second constituent encoder.

FIG. 5 illustrates an embodiment of an uplink encoding module that performs rate matching that includes the information (systematic) bits as well as the parity bits output from a first constituent encoder and a second constituent encoder.

FIG. 6 illustrates an embodiment of a downlink encoding module that performs rate matching that includes the information (systematic) bits as well as the parity bits output from a first constituent encoder and a second constituent encoder.

FIG. 7 is a diagram illustrating embodiment of a performance comparison of (1) turbo encoding with rate matching without puncturing the information (systematic) bits (shown as Re1.6 RM) and (2) turbo encoding with rate matching that includes puncturing of the information (systematic) bits (shown as Re1.6 RM+5% info puncturing).

FIG. 8 is a diagram illustrating embodiment of a method for performing information bit puncturing for turbo coding with parameter selectable rate matching tailored to lower Eb/No (ratio of energy per bit to spectral noise density) without degrading BLER (Block Error Rate) performance.

FIG. 9 illustrates another embodiment of a communication system.

FIG. 10 illustrates an embodiment of an apparatus that is operable to perform turbo encoding and/or turbo decoding.

FIG. 11 illustrates an alternative embodiment of an apparatus that is operable to perform turbo encoding and/or turbo decoding.

FIG. 12 illustrates another embodiment of a communication system.

### DETAILED DESCRIPTION OF THE INVENTION

Many communication systems incorporate the use of a turbo code. While there are many potential applications that can employ turbo codes, means are presented herein that can be applied to the 3GPP channel code to support an arbitrary number of information bits. Some examples of the number of bits, though not limited thereto, that can be supported using the various aspects of the invention presented herein are 40 to 5114 for WCDMA and HSDPA and more for LTE. Alternatively, other examples of the number of bits, though not limited thereto, that can be supported using the various aspects of the invention presented herein are 40 to 6114 or 40 to 8192, or any other desirable number of bits as selected for a particular application.

Additional information regarding the UTRA-UTRAN Long Term Evolution (LTE) and 3GPP System Architecture Evolution (SAE) can be found at the following Internet web site:

www.3gpp.org

Turbo coding was suggested for 3GPP LTE channel coding. Within the channel coding system in 3GPP LTE, there is a need and desire to supply and provide for a wide range of block sizes (i.e., turbo code block lengths). For this coding system, the algebraic interleave referred to as the “almost regular permutation (ARP)” in reference [5] is considered as one of the candidates, and “quadratic polynomial permutation (QPP)” in reference [6] is considered as an alternative candidate.

A very brief description of the QPP interleave is provided here:

Quadratic Polynomial Permutation (QPP)

Additional details regarding the quadratic polynomial permutation (QPP) interleave (π) are presented below.

Let a turbo code block size, or an interleave size of the turbo code be L, then the following function

π(x)=f₁x+f₂x² mod(L)

where f₁ and f₂ are non-negative integers, is said to be a QPP over the ring permutation on Z_{L}={0,1, . . . ,L−1}, when π(x) permutes {0,1, . . . ,L−1}. This is referred to as a quadratic polynomial as described in reference [6].

Denote the set of prime numbers by P={2,3, . . . }. Denote L=Π_{pεP}pⁿ^{_{L,p}}. Then a necessary and sufficient condition [5] for f(x) to be QPP is

1) when n_{L,2}≠1, gcd(f₁, L)=1 and f₂=Π_{pεP}pⁿ^{_{f2p}}^{_{,p}} such that n_{f}_{₂}_{,p}≧1 if n_{L,p}≧1;

2) when n_{L,2}=1, f₁+f₂ is odd, gcd(f₁, N/2)=1 and f₂=Π_{pεP}pⁿ^{_{f2p}}^{_{,p}} such that p≠2 and n_{f}_{₂}_{,p}≧1 if n_{L,p}≧1.

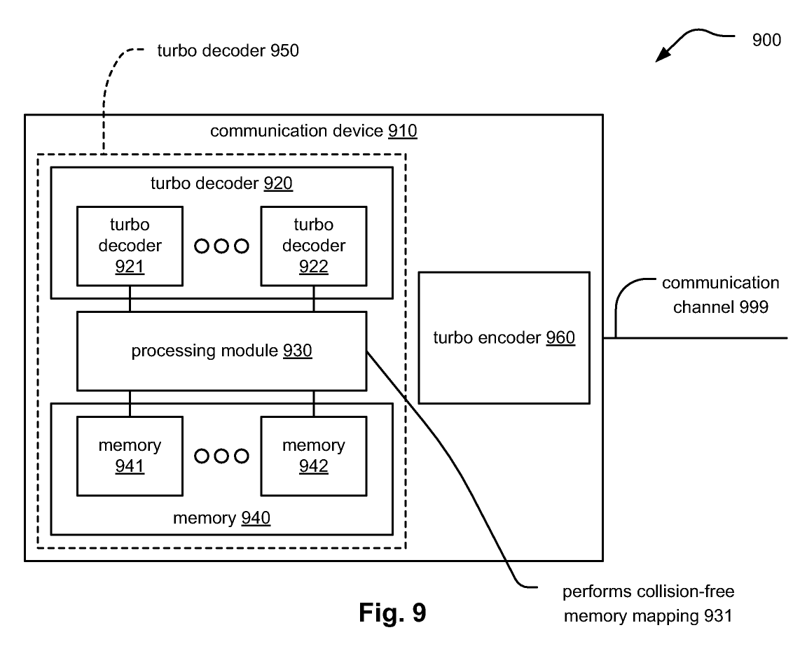

Furthermore, the turbo decoding of this system generally needs to be implemented using a parallel decoding arrangement because of the very high data throughput and large block size desired for 3GPP LTE channel coding (e.g., see FIG. 9). The parallel decoding requires the collision-free memory accessing (i.e., any one turbo decoder (of a group of parallel arranged turbo decoders) accesses only memory (of a group of parallel arranged memories) at any given time).

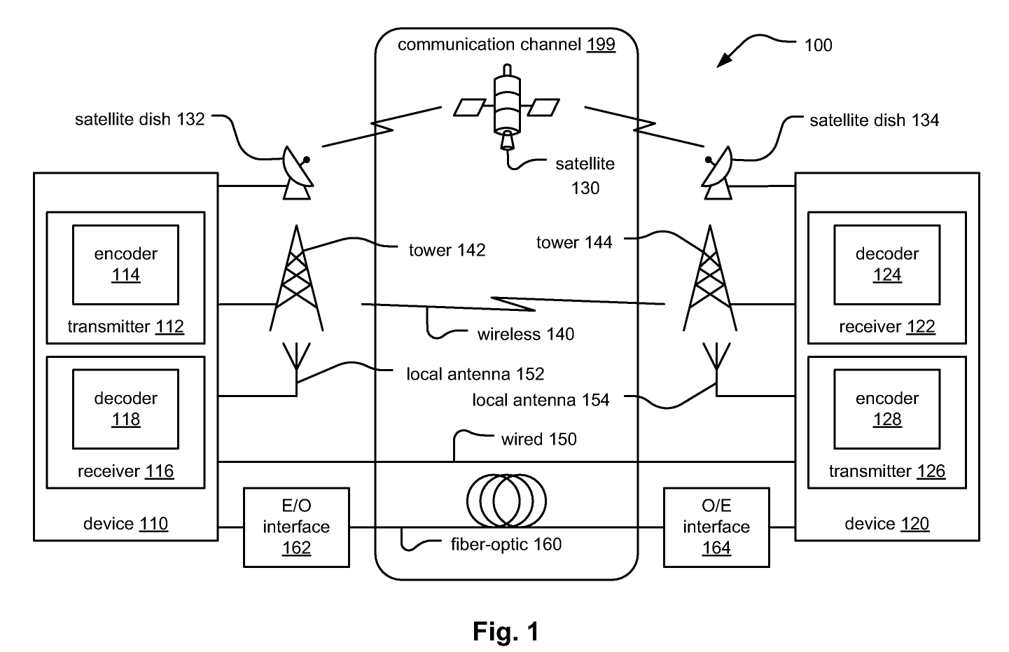

The goal of digital communications systems is to transmit digital data from one location, or subsystem, to another either error free or with an acceptably low error rate. As shown in FIG. 1, data may be transmitted over a variety of communications channels in a wide variety of communication systems: magnetic media, wired, wireless, fiber, copper, and other types of media as well.

FIG. 1 is a diagram illustrating an embodiment of a communication system 100.

Referring to FIG. 1, this embodiment of a communication system 100 is a communication channel 199 that communicatively couples a communication device 110 (including a transmitter 112 having an encoder 114 and including a receiver 116 having a decoder 118) situated at one end of the communication channel 199 to another communication device 120 (including a transmitter 126 having an encoder 128 and including a receiver 122 having a decoder 124) at the other end of the communication channel 199. In some embodiments, either of the communication devices 110 and 120 may only include a transmitter or a receiver. There are several different types of media by which the communication channel 199 may be implemented (e.g., a satellite communication channel 130 using satellite dishes 132 and 134, a wireless communication channel 140 using towers 142 and 144 and/or local antennae 152 and 154, a wired communication channel 150, and/or a fiber-optic communication channel 160 using electrical to optical (E/O) interface 162 and optical to electrical (O/E) interface 164)). In addition, more than one type of media may be implemented and interfaced together thereby forming the communication channel 199.

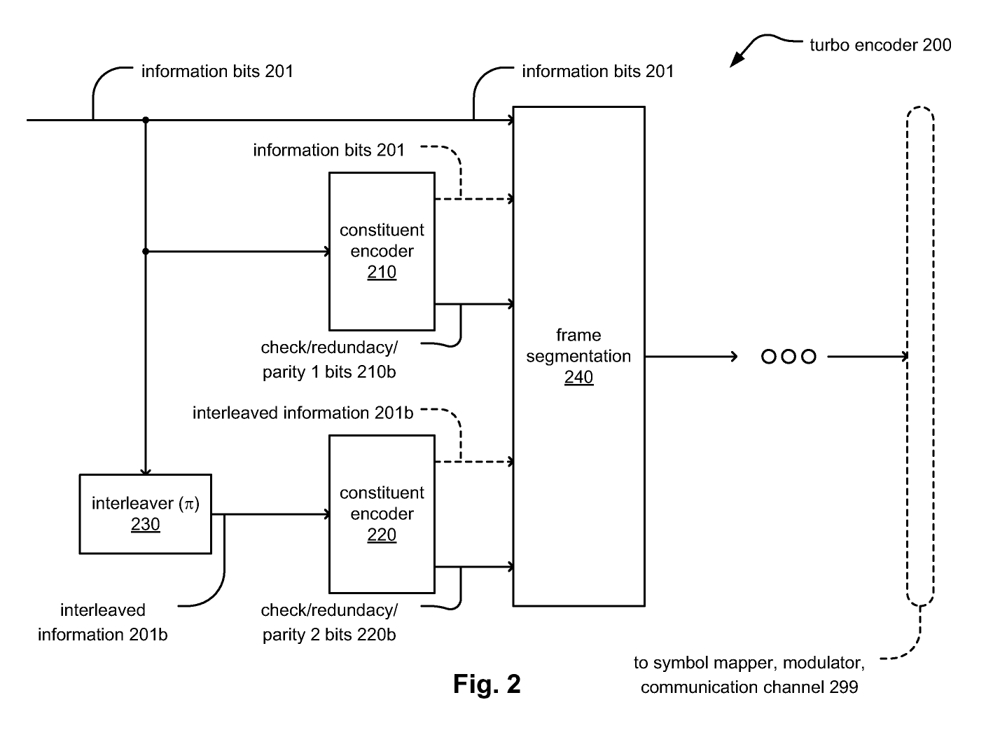

FIG. 2 illustrates an embodiment of a turbo encoding module 200. Information bits are provided to an interleaver (π) module 230 that is operable to generate interleaved information 201b. The interleave (π) employed by the interleaver (π) module 230 can be a QPP interleave (π) in some embodiments. Alternatively, other desired interleaves (π) can be employed by the interleaver (π) module 230 without departing from the scope and spirit of the invention.

These information bits 201 are also passed to a first constituent encoder 210 from which both the information bits 201 as well as check/redundancy/parity 1 bits 210b are output there from.

The interleaved information 201b output from the interleaver (π) module 230 is also passed to a second constituent encoder 220 from which both the interleaved information 201b as well as check/redundancy/parity 2 bits 220b are output there from.

In the art, the parity bits output from a turbo encoder are sometimes referred to as check bits, parity bits, and/or redundancy bits. Moreover, the information bits output from a turbo encoder are sometimes referred to as the information bits (i.e., the very same as was provided to the turbo encoder) and also as systematic bits (e.g., in the context of a systematic encoder that, when encoding information bits, outputs those same information bits as well as check/redundancy/parity bits). Herein, parity bits and is oftentimes employed for reference to these check/redundancy/parity bits output from a turbo encoder, and information bits is oftentimes employed for reference to these information/systematic bits output from a turbo encoder.

Each of the information bots 201, the parity 1 bits 210b, and the parity 2 bits 220b is provided to a frame segmentation module 240. Various other components can also be situated as part of or after the frame segmentation module 240 to assist in the generation of an encoded bloc that may then be passed to a symbol mapper where the symbols are mapped according to the appropriate modulation (constellation and mapping). These symbol mapped symbols may then undergo any appropriate modulation as required to generate a continuous-time signal whose format comports with a communication channel into which the turbo coded signal is to be launched.

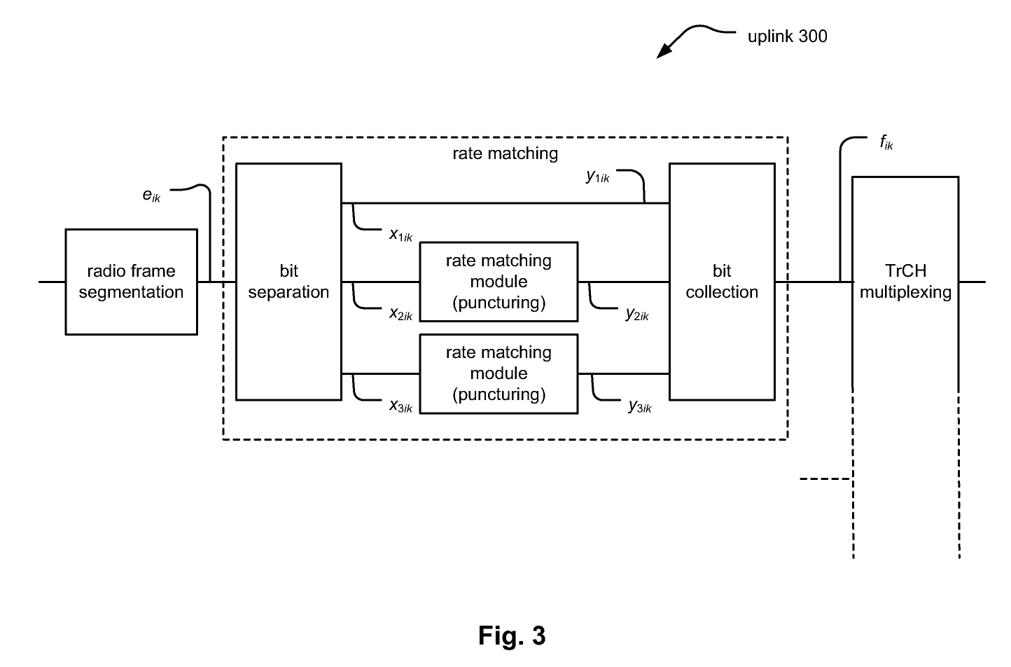

FIG. 3 illustrates an embodiment of an uplink encoding module 300 that performs rate matching to only the parity bits output from a first constituent encoder and a second constituent encoder.

In reference [1] (which deals with channel coding in 3GPP TS 25.212), the bit sequence provided from a radio frame segmentation module (shown as eᵢₖ) is separated into 3 parts within a bit separation module (i.e., as x₁ᵢₖ (information bits), x₂ᵢₖ (parity 1 bits from a first constituent encoder), and x₂ᵢₖ (parity 2 bits from a second constituent encoder)) before sending to a rate matching module that only performs puncturing in accordance with rate matching.

For example, the bit sequence {x₁ᵢₖ,k=0, . . . ,N−1} (where N is the block size) is the systematic bit sequence of the turbo encoded codeword. The bit sequence {x₂ᵢₖ,k=0, . . . ,N−1} is the parity 1 bit sequence obtained from the constituent encoder 1, and the bit sequence {x₃ᵢₖ,k=0, . . . ,N−1} is the parity 2 bit sequence obtained from the constituent encoder 2.

As can be seen, the only puncturing in accordance with rate matching is on the 2 bit sequences: x₂ᵢₖ (parity 1 bits from a first constituent encoder) and x₃ᵢₖ (parity 2 bits from a second constituent encoder).

A bit collection module then receives the bit sequence {x₁ᵢₖ,k=0, . . . ,N−1}={y₁ᵢₖ,k=0, . . . ,N−1}, and the now-punctured parity 1 bit sequence {y₂ᵢₖ,k=0, . . . ,N−1} as well as the now-punctured parity 2 bit sequence {y₃ᵢₖ,k=0, . . . ,N−1}.

The bit collection module is operable to generate a single bit sequence, fᵢₖ, to be provided to a TrCH multiplexing module. Various other components can also be situated as part of or after the TrCH multiplexing module to assist in the generation of an encoded bloc that may then be passed to a symbol mapper where the symbols are mapped according to the appropriate modulation (constellation and mapping). These symbol mapped symbols may then undergo any appropriate modulation as required to generate a continuous-time signal whose format comports with a communication channel into which the turbo coded signal is to be launched.

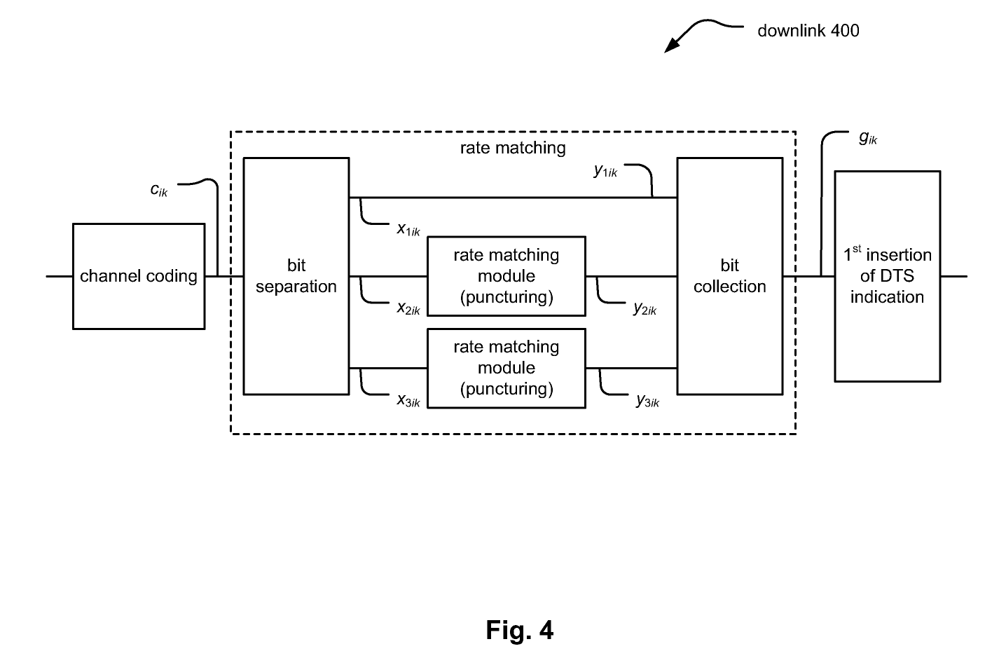

FIG. 4 illustrates an embodiment of a downlink encoding module 400 that performs rate matching to only the parity bits output from a first constituent encoder and a second constituent encoder. This embodiment is very analogous to the previous embodiment, except this embodiment operates for the downlink path.

A bit sequence provided from a channel coding module (shown as cᵢₖ) is separated into 3 parts within a bit separation module (i.e., as x₁ᵢₖ (information bits), x₂ᵢₖ (parity 1 bits from a first constituent encoder), and x₃ᵢₖ (parity 2 bits from a second constituent encoder)) before sending to a rate matching module that again only performs puncturing in accordance with rate matching.

For example, the bit sequence {x₁ᵢₖ,k=0, . . . ,N−1} (where N is the block size) is the systematic bit sequence of the turbo encoded codeword. The bit sequence {x₂ᵢₖ,k=0, . . . ,N−1} is the parity 1 bit sequence obtained from the constituent encoder 1, and the bit sequence {x₃ᵢₖ,k=0, . . . ,N−1} is the parity 2 bit sequence obtained from the constituent encoder 2.

As can be seen, the only puncturing in accordance with rate matching is on the 2 bit sequences: x₂ᵢₖ (parity 1 bits from a first constituent encoder) and x₃ᵢₖ (parity 2 bits from a second constituent encoder).

A bit collection module then receives the bit sequence {x₁ᵢₖ,k=0, . . . ,N−1}={y₁ᵢₖ,k=0, . . . ,N−1}, and the now-punctured parity 1 bit sequence {y₂ᵢₖ,k=0, . . . ,N−1} as well as the now-punctured parity 2 bit sequence {y₃ᵢₖ,k=0, . . . ,N−1}.

The bit collection module is operable to generate a single bit sequence, gᵢₖ, to be provided to a module that is operable to perform the 1^{st} insertion of DTS indication. Various other components can also be situated as part of or after the module that is operable to perform the 1^{st} insertion of DTS indication to assist in the generation of an encoded bloc that may then be passed to a symbol mapper where the symbols are mapped according to the appropriate modulation (constellation and mapping). These symbol mapped symbols may then undergo any appropriate modulation as required to generate a continuous-time signal whose format comports with a communication channel into which the turbo coded signal is to be launched.

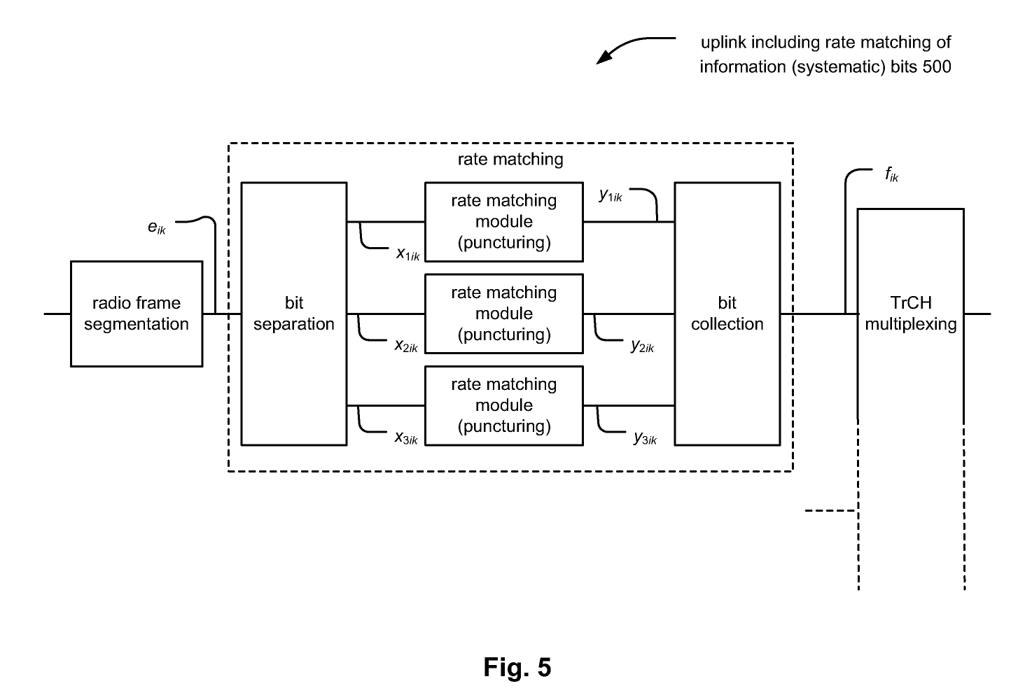

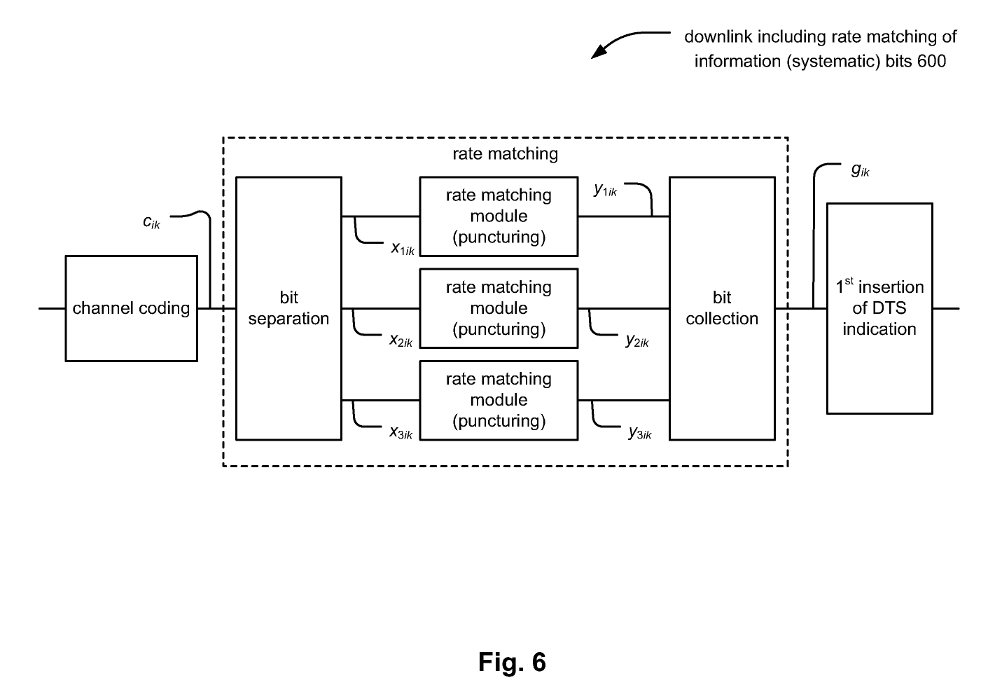

In the following embodiments FIG. 5 and FIG. 6, it can be seen that there is puncturing in accordance with rate control for all of the bits (e.g., for the information (systematic) bits as well as the parity bits output from a first constituent encoder and a second constituent encoder).

FIG. 5 illustrates an embodiment of an uplink encoding module 500 that performs rate matching that includes the information (systematic) bits as well as the parity bits output from a first constituent encoder and a second constituent encoder.

Generally speaking, puncturing the information (systematic) bits was proposed for circular buffer rate matching as described in reference [2]. However, that approach has certain guidelines and only when certain conditions are met is any puncturing performed to the information (systematic) bits. According to that approach in reference [2], there are instances where no puncturing is performed to the information (systematic) bits. Moreover, that approach in reference [2] operates on the supposition that there is a prioritization among the information (systematic) bits, the parity bits output from a first constituent encoder, and the parity bits output from a second constituent encoder. This can result in different operation at different times based on the prioritization scheme implemented.

The novel approach presented herein to perform puncturing to the information (systematic) bits as well as the parity bits output from a first constituent encoder, and a second constituent encoder operates without regard to any prioritization of the information (systematic) bits, the parity bits output from a first constituent encoder, and a second constituent encoder. Any or all of the information (systematic) bits, the parity bits output from a first constituent encoder, and the parity bits output from a second constituent encoder can undergo puncturing according to the novel approach presented herein without departing from the scope and spirit of the invention.

Referring to FIG. 5, the bit sequence provided from a radio frame segmentation module (shown as eᵢₖ) is separated into 3 parts within a bit separation module (i.e., as X₁ᵢₖ (information bits), x₂ᵢₖ (parity 1 bits from a first constituent encoder), and x₃ᵢₖ (parity 2 bits from a second constituent encoder)) before sending to a rate matching module that performs puncturing in accordance with rate matching to all of the 3 paths.

For example, the bit sequence {x₁ᵢₖ,k=0, . . . ,N−1} (where N is the block size) is the systematic bit sequence of the turbo encoded codeword. The bit sequence {x₂ᵢₖ,k=0, . . . ,N−1} is the parity 1 bit sequence obtained from the constituent encoder 1, and the bit sequence {x₃ᵢₖ,k=0, . . . ,N−1} is the parity 2 bit sequence obtained from the constituent encoder 2.

As can be seen, puncturing in accordance with rate matching is performed on all 3 bit sequences: x₁ᵢₖ (information bits), x₂ᵢₖ (parity 1 bits from a first constituent encoder), and x₂ᵢₖ (parity 2 bits from a second constituent encoder).

A bit collection module then receives the now-punctured bit sequence {y₁ᵢₖ,k=0, . . . ,N−1}, the now-punctured parity 1 bit sequence {y₂ᵢₖ,k=0, . . . ,N−1}, and the now-punctured parity 2 bit sequence {y₃ᵢₖ,k=0, . . . ,N−1}.

The bit collection module is operable to generate a single bit sequence, fᵢₖ, to be provided to a TrCH multiplexing module. Various other components can also be situated as part of or after the TrCH multiplexing module to assist in the generation of an encoded bloc that may then be passed to a symbol mapper where the symbols are mapped according to the appropriate modulation (constellation and mapping). These symbol mapped symbols may then undergo any appropriate modulation as required to generate a continuous-time signal whose format comports with a communication channel into which the turbo coded signal is to be launched.

FIG. 6 illustrates an embodiment of a downlink encoding module 600 that performs rate matching that includes the information (systematic) bits as well as the parity bits output from a first constituent encoder and a second constituent encoder.

A bit sequence provided from a channel coding module (shown as cᵢₖ) is separated into 3 parts within a bit separation module (i.e., as x₁ᵢₖ (information bits), X₂ᵢₖ (parity 1 bits from a first constituent encoder), and x₃ᵢₖ (parity 2 bits from a second constituent encoder)) before sending to a rate matching module that again only performs puncturing in accordance with rate matching.

For example, the bit sequence {X₁ᵢₖ,k=0, . . . ,N−1} (where N is the block size) is the systematic bit sequence of the turbo encoded codeword. The bit sequence {x₂ᵢₖ,k=0, . . . ,N−1} is the parity 1 bit sequence obtained from the constituent encoder 1, and the bit sequence {x₃ᵢₖ,k=0, . . . ,N−1} is the parity 2 bit sequence obtained from the constituent encoder 2.

As can be seen, puncturing in accordance with rate matching is performed on all 3 bit sequences: x₁ᵢₖ (information bits), x₂ᵢₖ (parity 1 bits from a first constituent encoder), and x₂ᵢₖ (parity 2 bits from a second constituent encoder).

A bit collection module then receives the now-punctured bit sequence {y₁ᵢₖ,k=0, . . . ,N−1}, the now-punctured parity 1 bit sequence {y₂ᵢₖ,k=0, . . . ,N−1}, and the now-punctured parity 2 bit sequence {y₃ᵢₖ,k=0, . . . , N−1}.

The bit collection module is operable to generate a single bit sequence, gᵢₖ, to be provided to a module that is operable to perform the 1^{st} insertion of DTS indication. Various other components can also be situated as part of or after the module that is operable to perform the 1^{st} insertion of DTS indication to assist in the generation of an encoded bloc that may then be passed to a symbol mapper where the symbols are mapped according to the appropriate modulation (constellation and mapping). These symbol mapped symbols may then undergo any appropriate modulation as required to generate a continuous-time signal whose format comports with a communication channel into which the turbo coded signal is to be launched.

More detail regarding the puncturing in accordance with rate matching (e.g., as can be performed within any of the rate matching modules) is provided here. This is described using the notation as follows:

(1) the bit sequence {x₁ᵢₖ,k=0, . . . ,N−1} (where N is the block size) is the information (e.g., systematic) bit sequence of the turbo encoded codeword;

(2) the bit sequence {x₂ᵢₖ,k=0, . . . ,N−1} is the parity 1 bit sequence obtained from the constituent encoder 1;

(3) the bit sequence {x₃ᵢₖ,k=0, . . . ,N−1} is the parity 2 bit sequence obtained from the constituent encoder 2.

The rate matching approach is as follows:
e=eᵢₙᵢ—initial error between current and desired puncturing ratio
m=1—index of current bit
do while m<=N
e=e−eₘᵢₙᵤₛ
if e<=0 then
   puncture the bit at position m
   e=e+eₚₗᵤₛ
end if
m=m+1—nextbit

where parameters eᵢₙᵢ, eₘᵢₙᵤₛ and eₚₗᵤₛ are given according to the code rate.

For example, consider a “mother” turbo code whose code rate is ⅓. Suppose the information block size is N and turbo code has an extra 12 termination bit. Then the number of punctured bits for rate R codeword is

$$Δ = \vert ⌈ \frac{N}{R} - 3 N - 12 ⌉ \vert$$

(e.g., this is the absolute value of the ceiling of the calculated

$$term “ \frac{N}{R} - 3 N - 12 ” ) .$$

Suppose one wants to puncture Δ₁ bits in parity 1 bit sequence, then the number of punctured bits in the parity 2 bit sequence is Δ₂=Δ−Δ₁.

Let a₁, a₂, b₁, b₂ be four constant numbers. Then the rate matching for the parity 1 bit sequence uses the following parameters:

eᵢₙᵢ=b₁N, eₚₗᵤₛ=a₁N, eₘᵢₙᵤₛ=a₁Δ₁, and the rate matching for the parity 2 bit sequence uses the following parameters:

eᵢₙᵢ=b₂N, eₚₗᵤₛ=a₂N, eₘᵢₙᵤₛ=a₂Δ₂.

With certain of the more recent interleaves as applied to turbo coding (e.g., the QPP interleave as described in reference [3] which are adopted for 3GPP LTE), it is shown that at higher code rate, the punctured code using the rate matching method in reference [1] has a very poor performance for some code block sizes (e.g., such as those which may be encountered in accordance with 3GPP LTE), especially for the interleave size of multiple 7, see [4]. To overcome this, puncture information bits may need.

To achieve the same code rate, the total punctured bits number is still Δ.

Suppose one need puncture Δ₀ information bits, Δ₁ and Δ₂ parity 1 bits for parity 2, respectively.

Then Δ=Δ₀+Δ₁+Δ₂.

Herein, a novel approach is presented using the same rate matching approach to puncture information bits with the parameters being as follows:

eᵢₙᵢ=b₀N, eₚₗᵤₛ=a₀N, eₘᵢₙᵤₛ=a₀Δ₀.

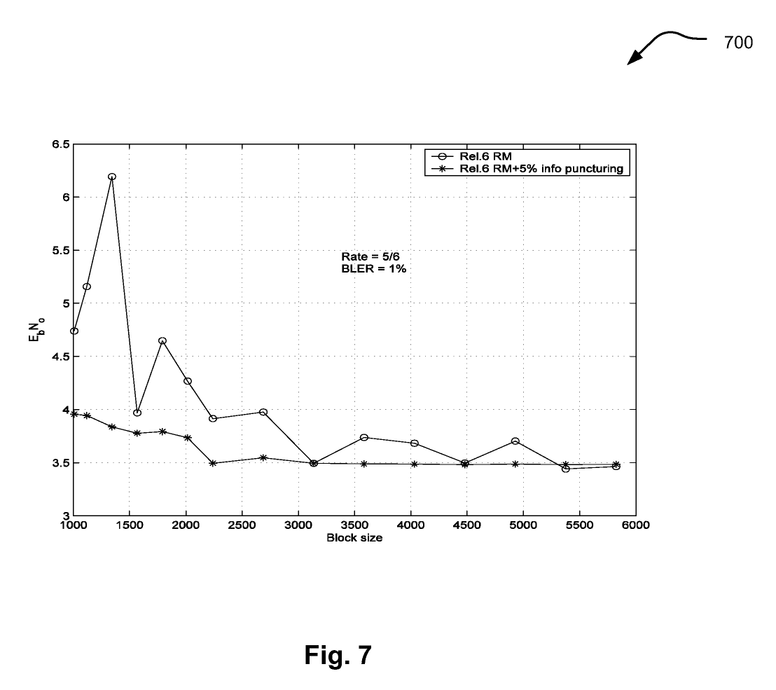

FIG. 7 is a diagram illustrating embodiment of a performance comparison 700 of (1) turbo encoding with rate matching without puncturing the information (systematic) bits (shown as Re1.6 RM) and (2) turbo encoding with rate matching that includes puncturing of the information (systematic) bits (shown as Re1.6 RM+5% info puncturing).

This performance diagram is described in the context of E_{b}/Nₒ (ratio of energy per bit E_{b} to the Spectral Noise Density Nₒ) versus block Size (e.g., described as “N” in some above embodiments).

Oftentimes performance diagrams are described in the context of BLER (Block Error Rate) [or BER (Bit Error Rate)] versus E_{b}/Nₒ (ratio of energy per bit E_{b} to the Spectral Noise Density Nₒ). This term E_{b}/Nₒ is the measure of SNR (Signal to Noise Ratio) for a digital communication system. When looking at such performance curves, the BLER [or BER] may be determined for any given E_{b}/Nₒ (or SNR) thereby providing a relatively concise representation of the performance of the decoding approach.

However, in this diagram, the BLER is fixed at being no more than 1%. This allows a quick, pictorial representation of the two types of turbo encoding in a single graph. In this example, the interleave sizes employed are as follows: 1008, 1120, 1344, 1568, 1792, 2016, 2240, 2688, 3136, 3584, 4032, 4480, 4928, 5376, 5824.

They are all multiple of 7. Consider rate ⅚ codes. Instead of puncturing the parity bits only (e.g., only the parity 1 bit sequence output from a first constituent encoder of a turbo encoder and the parity 2 bit sequence output from a second constituent encoder of a turbo encoder) as suggested by reference [1] (called Re1.6 in the diagram), the line that indicates “+5% information puncturing” performs puncturing in accordance with rate matching of 5% of the information bits. In this diagram, it can be seen that for virtually all of these block sizes, the turbo encoding with rate matching that includes puncturing of the information (systematic) bits (shown as Re1.6 RM+5% info puncturing) performs better (e.g., can operate with a lower E_{b}/Nₒ without suffering a degradation of BLER (or BER) performance). In the diagram, the BLER is approximately 1% for each of the two approaches to puncturing (i.e., (1) puncturing to only the parity bits from the first constituent encoder and the second constituent encoder and (2) puncturing to each of the three bit sequences including the information bits), yet the second means of performing puncturing (e.g., to each of the three bit sequences) is operable to achieve approximately the same BLER with significantly less energy (e.g., lower E_{b}/Nₒ). This can be very desirable in many types of communication systems including those where the energy budget within one or more communication devices is at a premium in the overall implementation.

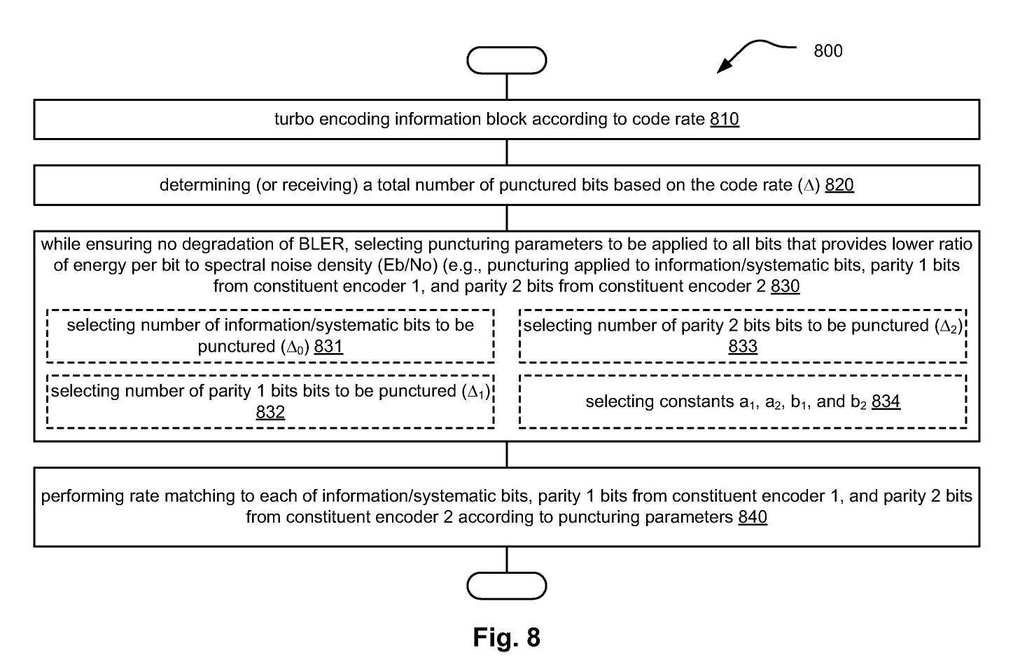

FIG. 8 is a diagram illustrating embodiment of a method 800 for performing information bit puncturing for turbo coding with parameter selectable rate matching tailored to lower Eb/No (ratio of energy per bit to spectral noise density) without degrading BLER (Block Error Rate) performance.

The method 800 begins by turbo encoding an information block according to code rate, as shown in a block 810. Based on this code rate at which the turbo encoding is performed, the method 800 then continues by determining (or receiving) a total number of punctured bits based on the code rate (e.g., which can be viewed as being Δ), as shown in a block 820.

As shown in a block 830, the method 800 operates by selecting puncturing parameters to be applied to all bits that to provide a lower E_{b}/Nₒ without incurring a degradation of BLER performance. Generally speaking, these puncturing parameters are selected for use in performing rate matching, and the puncturing parameters are applied to each of the 3 bit sequences of information/systematic bits, parity 1 bits from constituent encoder 1, and parity 2 bits from constituent encoder 2. The number of these puncturing parameters can be varied, and seven puncturing parameters are employed in one possible embodiment.

In one embodiment, based on the total number of punctured bits (e.g., Δ), then the number of bits to be punctured from each of the information/systematic bits, parity 1 bits from constituent encoder 1, and parity 2 bits from constituent encoder 2 can then be selected. For example, the method 800 can operate by selecting the number of information/systematic bits to be punctured (e.g., Δ₀) in accordance with the rate matching, as shown in a block 831. The method 800 can operate by selecting the number of parity 1 bits from constituent encoder 1 (e.g., Δ₁) in accordance with the rate matching, as shown in a block 832. The method 800 can also operate by selecting the number of parity 2 bits from constituent encoder 2 (e.g., Δ₂) in accordance with the rate matching, as shown in a block 833. It is noted that the relationship of these values is as follows:

Δ=Δ₀+Δ₁+Δ₂

As also described in embodiments above that employs the use of certain constant values in performing the rate matching, the method 800 can also operate by selecting constants (e.g., a₁,a₂,b₁,b₂) as shown in a block 834 for use in performing puncturing to effectuate rate matching as applied to each of the information/systematic bits, parity 1 bits from constituent encoder 1, and parity 2 bits from constituent encoder 2.

After selecting the appropriate puncturing parameters to be applied to all bits that to provide a lower E_{b}/Nₒ without incurring a degradation of BLER performance, the method 800 continues by performing rate matching to each of information/systematic bits, parity 1 bits from constituent encoder 1, and parity 2 bits from constituent encoder 2 according to puncturing parameters, as shown in a block 840. In addition, the particular puncturing perform in accordance with the puncturing parameters does not incur a reduction in error rate performance (e.g., BLER or BER performance) when compared to performing puncturing to only the parity 1 bits from constituent encoder 1, and parity 2 bits from constituent encoder 2.

FIG. 9 illustrates another embodiment of a communication system 900. The communication system 900 includes a communication device 910 that can be coupled to another device via a communication channel 999. The communication device 910 includes a turbo decoder 920 that is itself composed of a plurality of turbo decoders 921-922. The communication device 910 can also include a turbo encoder to facilitate bi-directional communication via the communication channel 999. The communication device 910 also includes a memory 940 that is itself composed of a plurality of memories 941-942. A processing module 930 is operable to perform collision-free memory mapping between the plurality of turbo decoders 921-922 and the plurality of memories 941-942 during iterative decoding processing of a turbo coded signal.

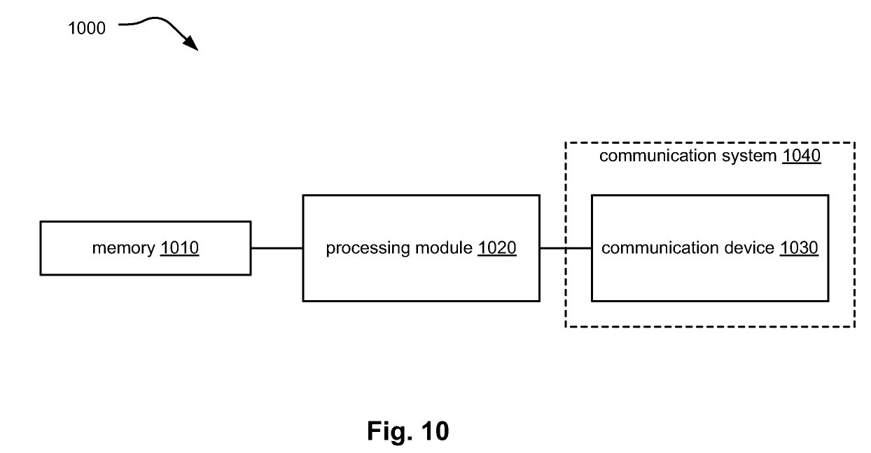

FIG. 10 illustrates an embodiment of an apparatus 1000 that is operable to perform turbo encoding and/or turbo decoding. The apparatus 1000 includes a processing module 1020, and a memory 1010. The memory 1010 is coupled to the processing module, and the memory 1010 is operable to store operational instructions that enable the processing module 1020 to perform a variety of functions. The processing module 1020 is operable to perform and/or direct the manner in which turbo encoding and/or turbo decoding is to be performed in accordance with any embodiment described herein, or any equivalent thereof.

The processing module 1020 can be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 1010 may be a single memory device or a plurality of memory devices. Such a memory device may be a read-only memory, random access memory, volatile memory, non-volatile memory, static memory, dynamic memory, flash memory, and/or any device that stores digital information. Note that when the processing module 1020 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry.

If desired in some embodiments, the manner in which the turbo encoding and/or turbo decoding is to be performed can be provided from the apparatus 1000 to a communication system 1040 that is operable to employ and perform turbo encoding and/or turbo decoding. For example, information corresponding to the type of turbo encoding and/or turbo decoding can also be provided from the processing module 1020 to any of a variety of communication devices 1030 implemented within the communication system 1040 as well. In addition, the puncturing parameters to be employed when performing turbo encoding can be provided (or the puncturing parameters that were employed when performing turbo encoding) can also be provided from the processing module 1020 to any of a variety of communication devices 1030 implemented within the communication system 1040 as well. In addition, the manner in which such turbo encoding and/or turbo decoding is to be performed within any of a variety of communication devices 1030 implemented within the communication system 1040 can also be provided from the processing module 1020.

If desired, the apparatus 1020 can be designed to generate multiple means of performing turbo encoding and/or turbo decoding in accordance with multiple needs and/or desires as well. In some embodiments, the processing module 1020 can selectively provide different information (e.g., corresponding to different puncturing employed in accordance with turbo encoding, etc.) to different communication devices and/or communication systems. That way, different communication links between different communication devices can employ turbo codes, different means of puncturing, and/or means by which to perform turbo encoding and/or turbo decoding. Clearly, the processing module 1020 can also provide the same information to each of different communication devices and/or communication systems as well without departing from the scope and spirit of the invention.

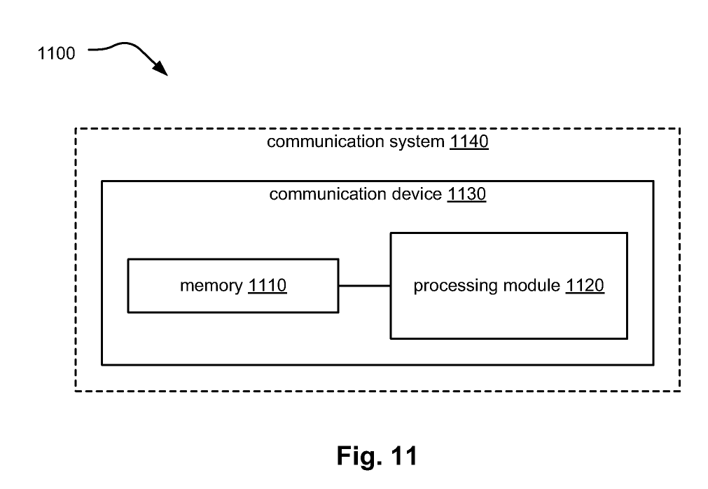

FIG. 11 illustrates an alternative embodiment of an apparatus 1100 that is operable to perform turbo encoding and/or turbo decoding. The apparatus 1100 includes a processing module 1120, and a memory 1110. The memory 1110 is coupled to the processing module, and the memory 1110 is operable to store operational instructions that enable the processing module 1120 to perform a variety of functions. The processing module 1120 (serviced by the memory 1120) can be implemented as an apparatus capable to perform any of the functionality of any of the various modules and/or functional blocks described herein. For example, the processing module 1120 (serviced by the memory 1120) can be implemented as an apparatus capable to perform and/or direct the manner in which turbo encoding and/or turbo decoding is to be performed in accordance with any embodiment described herein, or any equivalent thereof.

The processing module 1120 can be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 1110 may be a single memory device or a plurality of memory devices. Such a memory device may be a read-only memory, random access memory, volatile memory, non-volatile memory, static memory, dynamic memory, flash memory, and/or any device that stores digital information. Note that when the processing module 1120 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry.

If desired in some embodiments, the apparatus 1100 can be any of a variety of communication devices 1130, or any part or portion of any such communication device 1130. Any such communication device that includes the processing module 1120 and/or memory 1110 can be implemented within any of a variety of communication systems 1140 as well. It is also noted that various embodiments of turbo encoding and/or turbo decoding as presented herein, and equivalents thereof, may be applied to many types of communication systems and/or communication devices.

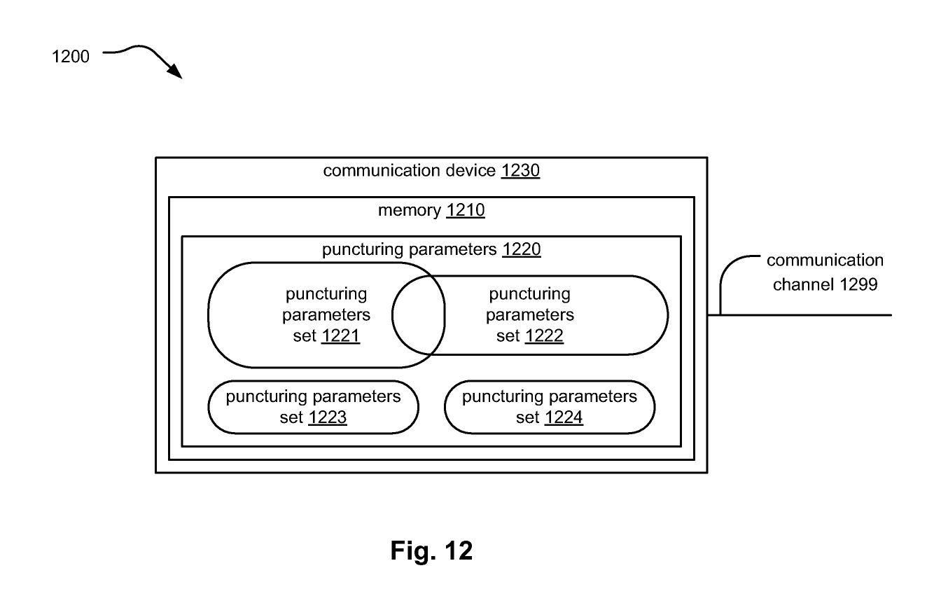

FIG. 12 illustrates another embodiment of a communication system 1200. The communication system 1200 includes a communication device 1230 coupled to a communication channel 1299. The communication device 1230 includes a processing module 1220, and a memory 1210. The memory 1210 is coupled to the processing module, and the memory 1210 is operable to store operational instructions that enable the processing module 1220 to perform a variety of functions. The processing module 1220 (serviced by the memory 1220) can be implemented as an apparatus capable to perform any of the functionality of any of the various modules and/or functional blocks described herein.

The memory 1210 is operable to store a first plurality of puncturing parameters 1220. A second plurality of puncturing parameters can be selected from the first plurality of puncturing parameters 1220 to govern the manner in which puncturing is to be performed when performing turbo encoding. A puncturing parameters set 1221 and a puncturing parameters set 1222 each include some of the same puncturing parameters. The memory 1210 also can include other puncturing parameters sets (e.g., puncturing parameters set 1223 and puncturing parameters set 1224, and others).

The manner in which puncturing may be performed within the communication device 1230 can be adaptive and/or changeable, in that, first puncturing parameters may be employed at a first time and second puncturing parameters may be employed at a second time, etc.

It is noted that the various modules (e.g., encoding modules, rate matching modules, interleavers, etc.) described herein may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The operational instructions may be stored in a memory. The memory may be a single memory device or a plurality of memory devices. Such a memory device may be a read-only memory, random access memory, volatile memory, non-volatile memory, static memory, dynamic memory, flash memory, and/or any device that stores digital information. It is also noted that when the processing module implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry. In such an embodiment, a memory stores, and a processing module coupled thereto executes, operational instructions corresponding to at least some of the steps and/or functions illustrated and/or described herein.

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention.

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

### REFERENCES

[1] 3^{rd} Generation Partnership Project; Technical Specification Group Radio Access Network; Multiplexing and channel coding (FDD) (Release 6), 3GPP TS 25.212 V6.8.0 (June 2006).

[2] R1-071195, Motorola, Turbo rate-matching in LTE. 3GPP TSG RAN WG1#48bis, St. Julians, Malta, Mar. 26-30, 2007.

[3] R1-071195, Ericsson, Motorola, Broadcom, ZTE, Nokia, Texas Instruments, Qualcomm Europe, Freescale, CATT, ITRI, NTT DoCoMo, Panasonic, Samsung, Mitsubishi, Nortel, “QPP Interleaver Parameters,” 3GPP TSG RAN WG1#48, St. Louis, USA, Feb. 12-16, 2007.

[4] R1-071589, Motorola, Performance Study of Rate Matching Algorithms 3GPP TSG RAN WG1#48bis, St. Julians, Malta, Mar. 26-30, 2007.

[5] C. Berrou, Y. Saouter, C. Douillard, S. Kerouedan, and M. Jezequel, “Designing good permutations for turbo codes: towards a single model,” 2004 IEEE International Conference on Communications (ICC), Vol. 1, pp: 341-345, 20-24 Jun. 2004.

[6] Oscar Y. Takeshita, “On maximum contention-free interleavers and permutation polynomials over integer rings,” IEEE Transactions on Information Theory, Vol. 52, No. 3, March 2006, pp. 1249-1253.

What is claimed is:

1. A turbo encoder, comprising:
a first constituent encoder that is operable to encode an information block thereby generating a first plurality of information bits and a first plurality of parity bits;
an interleaver module that is operable to interleave the information block thereby generating interleaved information;
a second constituent encoder that is operable to encode the interleaved information thereby generating a second plurality of information bits and a second plurality of parity bits;
a bit separation module that is operable to separate the information block, the first plurality of parity bits, and the second plurality of parity bits into three separate bit sequences, respectively;
a rate matching module that is operable to perform puncturing to each of the three separate bit sequences; and
a bit collection module that is operable to generate an output bit sequence that includes the three separate bit sequences, after each has undergone puncturing in the rate matching module; and wherein:
the output bit sequence undergoes modulation to generate a turbo coded signal that comports with a communication channel; and
the turbo coded signal is launched into the communication channel.

2. The turbo encoder of claim 1, wherein:
the puncturing of each of the three separate bit sequences in the rate matching module is operable to provide a lower E_{b}/Nₒ, without incurring a reduction in error rate performance, than performing puncturing to only the first plurality of parity bits and the second plurality of parity bits.

3. The turbo encoder of claim 1, wherein:
the turbo encoder is implemented in a first communication device;
the first communication device is a coupled to a second communication device via the communication channel;
the second communication device is operable to receive the turbo coded signal from the communication channel; and
the second communication device includes a plurality of turbo decoders implemented to perform parallel decoding processing of the turbo coded signal.

4. The turbo encoder of claim 1, wherein:
the turbo encoder is implemented within a first communication device;
at least one additional turbo encoder is implemented within a second communication device;
the first communication device and the second communication device are coupled via the communication channel;
the first communication device is operable to generate the turbo coded signal for uplink transmission via the communication channel; and
the second communication device is operable to generate at least one additional turbo coded signal for downlink transmission via the communication channel.

5. The turbo encoder of claim 1, further comprising:
a memory that is operable to store a plurality of puncturing parameters sets; and wherein:
the puncturing of each of the three separate bit sequences in the rate matching module is performed in accordance with one set of the plurality of puncturing parameter sets.

6. The turbo encoder of claim 1, further comprising:
a memory that is operable to store a first plurality of puncturing parameters; and wherein:
the puncturing of each of the three separate bit sequences in the rate matching module is performed in accordance with a second plurality of puncturing parameters that is selected from the first plurality of puncturing parameters.

7. The turbo encoder of claim 1, further comprising:
a memory that is operable to store a plurality of puncturing parameters sets; and wherein:
the puncturing of each of the three separate bit sequences in the rate matching module is performed in accordance with a first set of the plurality of puncturing parameter sets;
the first set of the plurality of puncturing parameter sets is operable to puncture a first number of bits within the information block, a second number of bits within the first plurality of parity bits, and third number of bits within the second plurality of parity bits;
a second set of the plurality of puncturing parameter sets is operable to puncture a fourth number of bits within the information block, a fifth number of bits within the first plurality of parity bits, and sixth number of bits within the second plurality of parity bits;
the first number of bits plus the second number of bits plus the third number of bits add to a total number of bits; and
the fourth number of bits plus the fifth number of bits plus the sixth number of bits also add to the total number of bits.

8. The turbo encoder of claim 1, further comprising:
a memory that is operable to store a plurality of puncturing parameters sets; and wherein:
each puncturing parameters set of the plurality of puncturing parameters sets is operable to perform puncturing to each of the three separate bit sequences such that each turbo coded signal generated thereby has a same code rate.

9. The turbo encoder of claim 1, wherein:
the turbo encoder is implemented within a wireless personal communication device.

10. The turbo encoder of claim 1, wherein:
the turbo encoder is implemented within a communication device; and
the communication device is implemented within at least one of a satellite communication system, a wireless communication system, a wired communication system, and a fiber-optic communication system.

11. A turbo encoder, comprising:
a memory that is operable to store a first plurality of puncturing parameters;
a first constituent encoder that is operable to encode an information block thereby generating a first plurality of information bits and a first plurality of parity bits;
an interleaver module that is operable to interleave the information block thereby generating interleaved information;
a second constituent encoder that is operable to encode the interleaved information thereby generating a second plurality of information bits and a second plurality of parity bits;
a bit separation module that is operable to separate the information block, the first plurality of parity bits, and the second plurality of parity bits into three separate bit sequences, respectively;
a rate matching module that is operable to perform puncturing to each of the three separate bit sequences in accordance with a second plurality of puncturing parameters that is selected from the first plurality of puncturing parameters; and
a bit collection module that is operable to generate an output bit sequence that includes the three separate bit sequences, after each has undergone puncturing in the rate matching module; and wherein:
the output bit sequence undergoes modulation to generate a turbo coded signal that comports with a communication channel;
the turbo coded signal is launched into the communication channel; and
the puncturing of each of the three separate bit sequences in the rate matching module that is performed in accordance with the second plurality of puncturing parameters is operable to provide a lower E_{b}/Nₒ, without incurring a reduction in error rate performance, than performing puncturing to only the first plurality of parity bits and the second plurality of parity bits.

12. The turbo encoder of claim 11, wherein:
the second plurality of puncturing parameters that is selected from the first plurality of puncturing parameters is operable to perform puncturing to each of the three separate bit sequences such that the turbo coded signal generated thereby has a first code rate; and
a third plurality of puncturing parameters that is selected from the first plurality of puncturing parameters is operable to perform puncturing to each of the three separate bit sequences such that at least one additional turbo coded signal generated thereby also has the first code rate.

13. The turbo encoder of claim 11, wherein:
the first plurality of puncturing parameters is operable to puncture a first number of bits within the information block, a second number of bits within the first plurality of parity bits, and third number of bits within the second plurality of parity bits;
a second plurality of puncturing parameters is operable to puncture a fourth number of bits within the information block, a fifth number of bits within the first plurality of parity bits, and sixth number of bits within the second plurality of parity bits;
the first number of bits plus the second number of bits plus the third number of bits add to a total number of bits; and
the fourth number of bits plus the fifth number of bits plus the sixth number of bits also add to the total number of bits.

14. The turbo encoder of claim 11, wherein:
the turbo encoder is implemented within a communication device; and
the communication device is implemented within a wireless communication system.

15. The turbo encoder of claim 11, wherein:
the turbo encoder is implemented within a communication device; and
the communication device is implemented within at least one of a satellite communication system, a wireless communication system, a wired communication system, and a fiber-optic communication system.

16. A method for turbo encoding at least one information bit, the method comprising:
encoding an information block thereby generating a first plurality of information bits and a first plurality of parity bits;
interleaving the information block thereby generating interleaved information;
encoding the interleaved information thereby generating a second plurality of information bits and a second plurality of parity bits;
separating the information block, the first plurality of parity bits, and the second plurality of parity bits into three separate bit sequences, respectively;
performing puncturing to each of the three separate bit sequences to provide rate matching;
generating an output bit sequence that includes the three separate bit sequences, after each has undergone puncturing;
modulating the output bit sequence to generate a turbo coded signal that comports with a communication channel; and
launching the turbo coded signal into the communication channel; and wherein:
when comparing puncturing to only the first plurality of parity bits and the second plurality of parity bits and the puncturing of each of the three separate bit sequences, the puncturing of each of the three separate bit sequences is operable to provide a lower E_{b}/Nₒ for the turbo coded signal and does not incur a reduction in error rate performance.

17. The method of claim 16, further comprising:
puncturing a first number of bits within the first plurality of parity bits; and
puncturing a second number of bits within the second plurality of parity bits.

18. The method of claim 16, wherein:
the puncturing of each of the three separate bit sequences in the rate matching module is performed in accordance with a first set of the plurality of puncturing parameter sets;
the first set of the plurality of puncturing parameter sets is operable to puncture a first number of bits within the information block, a second number of bits within the first plurality of parity bits, and third number of bits within the second plurality of parity bits;
a second set of the plurality of puncturing parameter sets is operable to puncture a fourth number of bits within the information block, a fifth number of bits within the first plurality of parity bits, and sixth number of bits within the second plurality of parity bits;
the first number of bits plus the second number of bits plus the third number of bits add to a total number of bits; and
the fourth number of bits plus the fifth number of bits plus the sixth number of bits also add to the total number of bits.

19. The method of claim 16, wherein:
the method is performed within a turbo encoder; and
the turbo encoder is implemented within a wireless communication device.

20. The method of claim 16, wherein:
the method is performed within a turbo encoder;
the turbo encoder is implemented within a communication device; and
the communication device is implemented within at least one of a satellite communication system, a wireless communication system, a wired communication system, and a fiber-optic communication system.
